(19) United States
(12) Patent Application Publication
(10) Pub. No.: US 2026/0040747 A1
(43) Pub. Date: Feb. 5, 2026

(54) DISPLAY PANEL, METHOD FOR MANUFACTURING THE SAME, AND DISPLAY DEVICE

(71) Applicant: HKC CORPORATION LIMITED, Shenzhen (CN)

(72) Inventors: QIN LIANG, Shenzhen (CN); Xiufeng ZHOU, Shenzhen (CN); Zhisheng XIE, Shenzhen (CN); Yangling TANG, Shenzhen (CN); Zhi YANG, Shenzhen (CN); Lidan YE, Shenzhen (CN)

(21) Appl. No.: 19/281,753

(22) Filed: Jul. 27, 2025

(30) Foreign Application Priority Data
Jul. 30, 2024 (CN) 202411031494.X

(51) Int. Cl. H10H 29/854; H10H 29/01; H10H 29/37; H10H 29/85; H10H 29/855

(52) U.S. Cl. CPC H10H 29/854; H10H 29/012; H10H 29/37; H10H 29/8517; H10H 29/855; H10H 29/8552

(57) ABSTRACT

A display panel, a method for manufacturing the display panel, and a display device are disclosed. The display panel includes a substrate, multiple partition structures, multiple light-emitting elements, and a first inorganic encapsulation layer. A pixel opening is formed between every two adjacent partition structures, thus obtaining multiple pixel openings. The multiple light-emitting elements are respectively arranged in the multiple pixel openings. The first inorganic encapsulation layer is disposed on and covers a side of the multiple light-emitting elements and the multiple partition structures facing away from the substrate. The display panel further includes a first organic encapsulation layer disposed between every two adjacent partition structures and a second organic encapsulation layer disposed on the side of the first organic encapsulation layer facing away from the substrate. The viscosity of the first organic encapsulation layer is lower than that of the second organic encapsulation layer.

### CROSS-REFERENCE TO RELATED APPLICATIONS

This application claims the priority and benefit of Chinese patent application number 202411031494X, titled “Display Panel, Method for Manufacturing the Same, and Display Device” and filed Jul. 30, 2024 with China National Intellectual Property Administration, the entire contents of which are incorporated herein by reference.

### TECHNICAL FIELD

This application relates to the field of display technology, and more particularly relates to a display panel, a method for manufacturing the same, and a display device.

### BACKGROUND

The description provided in this section is intended for the mere purpose of providing background information related to the present application but does not necessarily constitute prior art.

In the field of display panels, under the Fine Metal Mask (FMM)-less Technology, a partition structure is formed on the substrate by stacking a pixel defining layer, a conductive layer, and an insulating layer, thereby achieving the purpose of confining the deposition region of the vapor-deposited film layers, enabling a more cost-effective option for product development.

However, the design of the partition structure tends to affect the reliability of encapsulation.

Therefore, this is an urgent problem to be solved.

### SUMMARY

It is therefore one objective of this application to provide a display panel, a method for manufacturing the same, and a display device, in which the organic encapsulation filling interface is leveled to improve encapsulation reliability.

The present application discloses a display panel, including a substrate, a plurality of partition structures, a plurality of light-emitting elements, and a first inorganic encapsulation layer. The plurality of partition structures are arranged on the substrate and spaced apart from each other. A pixel opening is formed between every two adjacent partition structures, resulting in a plurality of pixel openings. The plurality of light-emitting elements are arranged within the plurality of pixel openings in one-to-one correspondence. The first inorganic encapsulation layer is disposed on and covers the side of the plurality of light-emitting elements and the plurality of partition structures facing away from the substrate. The display panel further includes a first organic encapsulation layer and a second organic encapsulation layer. The first organic encapsulation layer is arranged between every two adjacent partition structures. The second organic encapsulation layer is arranged on the side of the first organic encapsulation layer facing away from the substrate. The viscosity of the first organic encapsulation layer is lower than that of the second organic encapsulation layer.

In some embodiments, a leveling region is formed between every two adjacent partition structures. The height of the horizontal plane on which the upper surface of each first organic encapsulation layer is located is at least flush with or higher than the height of the horizontal plane on the upper surface of the leveling region is located. Furthermore, the height of the horizontal plane on which the upper surface of each first organic encapsulation layer is located is lower than the height of the horizontal plane on which the upper surface of the corresponding partition structure is located.

In some embodiments, the thickness of each first organic encapsulation layer is in the range of 1.5 μm to 4 μm. The thickness of each second organic encapsulation layer is in the range of 4 μm to 10 μm.

In some embodiments, each first organic encapsulation layer and each second organic encapsulation layer are made of an acrylic-based or epoxy-based organic material.

In some embodiments, the display panel further includes a third organic encapsulation layer. A plurality of second organic encapsulation layers are provided, and each second organic encapsulation layer is disposed between two adjacent partition structures. A third encapsulation groove is formed between two adjacent second organic encapsulation layers and the corresponding partition structure. The third organic encapsulation layer is disposed in the third encapsulation groove. The first organic encapsulation layer and the second organic encapsulation layer have the same refractive index. The refractive index of the third organic encapsulation layer is less than that of each of the first organic encapsulation layer and the second organic encapsulation layer.

In some embodiments, the refractive indices of the first organic encapsulation layer and the second organic encapsulation layer are each in the range of 1.6 to 1.8. The refractive index of the third organic encapsulation layer is greater than 1.4 and less than 1.5.

In some embodiments, the cross-section of the third organic encapsulation layer in a thickness direction of the substrate is a trapezoidal structure.

In some embodiments, each of the partition structures includes a pixel defining layer, a conductive layer, and an insulating layer that are stacked in sequence. The first inorganic encapsulation layer includes a first encapsulation piece and a second encapsulation piece that are disposed on the insulating layer and that are spaced apart from each other. A groove structure is formed among the first encapsulation piece, the insulating layer, and the second encapsulation piece.

The third organic encapsulation layer includes a first organic encapsulation piece and a second organic encapsulation piece that are stacked in sequence. The first organic encapsulation piece is embedded within the groove structure.

The cross-section of the second organic encapsulation piece in the thickness direction of the substrate is an upright trapezoidal structure. The second organic encapsulation piece includes a first inclined surface and a second inclined surface that are arranged opposite to each other. The angle between the first inclined surface and the horizontal plane, and the angle between the second inclined surface and the horizontal plane, are each denoted as angle a, where 60°≤a≤90°.

The present application further discloses a method for manufacturing a display panel, which is used for manufacturing the display panel as described above, the method including the following operations:
providing a substrate;
forming a plurality of pixel defining layers that are spaced apart from each other on the substrate, with a pixel opening formed between every two adjacent pixel defining layers;
sequentially forming a conductive layer and an insulating layer on each of the pixel defining layers, wherein the pixel defining layer, the conductive layer, and the insulating layer jointly form a partition structure;
forming a light-emitting element within each of the pixel openings;
forming a first inorganic encapsulation layer above the light-emitting elements and the partition structures;
forming a first organic encapsulation layer on the corresponding first inorganic encapsulation layer between the adjacent partition structures;
forming a second organic encapsulation layer on the first organic encapsulation layer;
etching the corresponding second organic encapsulation layer at the position corresponding to each partition structure to form a third encapsulation groove above the partition structure; and
forming a third organic encapsulation layer within the third encapsulation groove to complete the encapsulation of the display panel.

The present application further discloses a display device, including the above-mentioned display panel.

Compared to the issue in the related art where it is difficult to achieve desired filling and leveling in some narrow areas during the encapsulation of organic encapsulation layer, in the present application the display panel further includes a first organic encapsulation layer and a second organic encapsulation layer. The first organic encapsulation layer is disposed between two adjacent partition structures. The second organic encapsulation layer is disposed on the side of the first organic encapsulation layer facing away from the substrate. The viscosity of the first organic encapsulation layer is lower than that of the second organic encapsulation layer. In this manner, after printing the first inorganic encapsulation layer, the first organic encapsulation layer is printed. Since the first organic encapsulation layer has relatively lower viscosity, it has better flowability and can achieve better filling and leveling. Subsequently, the second organic encapsulation layer is printed to perform a second organic encapsulation using the higher-viscosity second organic encapsulation layer, thereby improving the encapsulation reliability.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principles of the present application in conjunction with the text description. Apparently, the drawings in the following description merely represent some embodiments of the present disclosure, and for those having ordinary skill in the art, other drawings may also be obtained based on these drawings without investing creative. In the drawings:

FIG. 1 is a schematic block diagram illustrating a structure of a display device provided in the present application.

FIG. 2 is a schematic diagram of a display panel provided in the present application.

FIG. 3 is a schematic cross-sectional view taken along line A-A′ in FIG. 2.

FIG. 4 is a schematic diagram of a film layer structure of a display panel according to a first embodiment of the present application.

FIG. 5 is a partially enlarged schematic view of portion B shown in FIG. 4.

FIG. 6 is a schematic flow diagram of a method for manufacturing a display panel provided in the present application.

FIG. 7 is a schematic diagram of a film layer structure of a display panel according to a second embodiment of the present application.

In the drawings: 10, display device; 100, display panel; 110, substrate; 120, partition structure; 121, pixel defining layer; 122, conductive layer; 123, insulating layer; 130, light-emitting element; 131, anode; 132, light-emitting layer; 133, cathode; 140, first inorganic encapsulation layer; 141, first encapsulation piece; 142, second encapsulation piece; 143, recess; 150, pixel opening; 160, first organic encapsulation layer; 170, second organic encapsulation layer; 180, leveling region; 190, third encapsulation groove; 200, third organic encapsulation layer; 210, first organic encapsulation piece; 220, second organic encapsulation piece; 221, first inclined surface; 222, second inclined surface; 223, first bottom surface; 224, first surface; 300, groove structure; 310, second inorganic encapsulation layer; 320, black matrix; 330, color filter layer; 340, first encapsulation interface; 350, second encapsulation interface.

### DETAILED DESCRIPTION OF EMBODIMENTS

It should be understood that the terms used herein, the specific structures and functional details disclosed therein are merely representative for describing some specific embodiments, but the present application can be implemented in many alternative forms and should not be construed as being limited to only these embodiments described herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. In addition, terms “up”, “down”, “left”, “right”, “second direction”, and “first direction”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure. For those of ordinary skill in the art, the specific meanings of the above terms as used in the present application can be understood depending on specific contexts.

As used herein, the term “upright trapezoid” refers to a trapezoidal shape that is positioned upright, such that the top base is relatively shorter and the bottom base is relatively longer. This orientation results in a structure that appears wider at the bottom and narrower at the top when viewed in cross section. In contrast, an “inverted trapezoid” is a trapezoidal shape positioned upside down, with the top base being relatively longer and the bottom base being relatively shorter, thereby creating a structure that is wider at the top and narrower at the bottom. These definitions are used throughout the present disclosure to describe the cross-sectional profiles of various structural layers in the display panel.

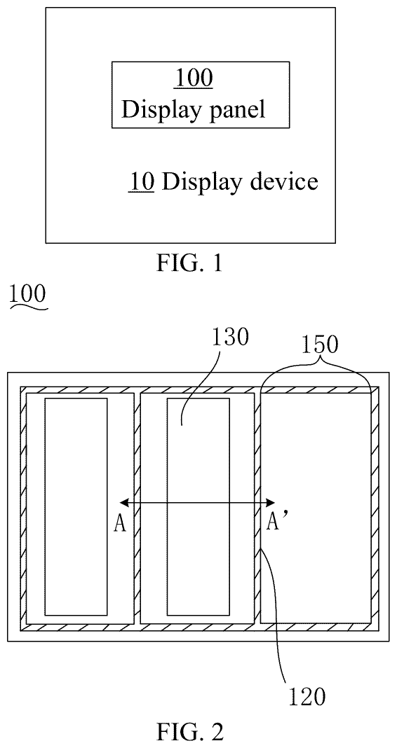

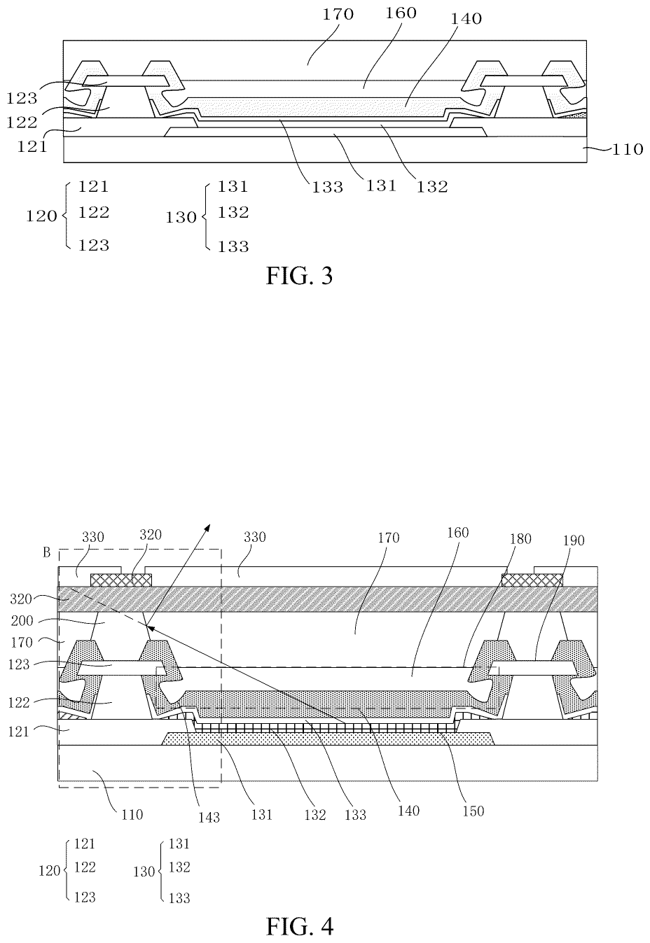

FIG. 1 is a schematic block diagram illustrating a structure of a display device provided in the present application. FIG. 2 is a schematic diagram of a display panel provided in the present application. FIG. 3 is a schematic cross-sectional view taken along line A-A′ in FIG. 2. As shown in FIGS. 1 to 3, the present application discloses a display device 10, which includes a display panel 100. The display panel 100 includes a substrate 110, a plurality of partition structures 120, a plurality of light-emitting elements 130, and a first inorganic encapsulation layer 140. The plurality of partition structures 120 are disposed on the substrate 110 with intervals therebetween. A pixel opening 150 is defined between two adjacent partition structures 120, thereby obtaining a plurality of pixel openings 150. The plurality of light-emitting elements 130 are disposed within the plurality of pixel openings 150 in one-to-one correspondence. The first inorganic encapsulation layer 140 is disposed to cover the side of the plurality of light-emitting elements 130 and the plurality of partition structures 120 facing away from the substrate 110. The display panel 100 further includes a first organic encapsulation layer 160 and a second organic encapsulation layer 170. The first organic encapsulation layer 160 is disposed between two adjacent partition structures 120. The second organic encapsulation layer 170 is disposed on the side of the first organic encapsulation layer 160 facing away from the substrate 110. The viscosity of the first organic encapsulation layer 160 is lower than the viscosity of the second organic encapsulation layer 170.

The partition structure in a related display panel resembles a mushroom-shaped structure. The conductive layer resembles a mushroom stem. The insulating layer resembles a mushroom cap located above the mushroom stem. The structural features between the conductive layer and the insulating layer tend to result in significant height variations at different positions in the region during the encapsulation of the first inorganic encapsulation layer after the vapor deposition of the light-emitting layer and the cathode. The inventor(s) of the present application have found that such a design may lead to problems where the subsequent organic encapsulation layer cannot fill and level well in some narrow regions. Therefore, the present application proposes that the display panel 100 further includes a first organic encapsulation layer 160 and a second organic encapsulation layer 170. The first organic encapsulation layer 160 is disposed between two adjacent partition structures 120. The second organic encapsulation layer 170 is disposed on the side of the first organic encapsulation layer 160 facing away from the substrate 110. The viscosity of the first organic encapsulation layer 160 is lower than that of the second organic encapsulation layer 170. In this manner, after printing the first inorganic encapsulation layer 140, the first organic encapsulation layer 160 is printed. Since the first organic encapsulation layer 160 has relatively lower viscosity, it has better flowability and can achieve better filling and leveling. Subsequently, the second organic encapsulation layer 170 is printed to perform a second organic encapsulation using the higher-viscosity second organic encapsulation layer 170, thereby improving the encapsulation reliability.

The present application will be described in detail below with reference to the accompanying drawings and some optional embodiments.

### First Embodiment

The first organic encapsulation layer 160 and the second organic encapsulation layer 170 are made of acrylic-based or epoxy-based organic materials. Both materials are in liquid form and have a small-molecule organic monomer structure. They can be cured into polymers by heating with an external heat source. Taking the acrylic-based organic material as an example, if the monomer is a single-component small molecule, its viscosity can be adjusted by modifying the branched chain structure of the organic monomer. An acrylic resin-based organic material may be used, which provides a superior leveling effect. Compared with using organic materials formed by mixing a solute and an ink solvent, it is more convenient as there is no need to adjust the solute-to-solvent ratio. Of course, the first organic encapsulation layer 160 and the second organic encapsulation layer 170 may also adopt a solute-solvent mixed solution scheme, which can be selected based on the specific requirements of the display panel 100, and is not limited herein.

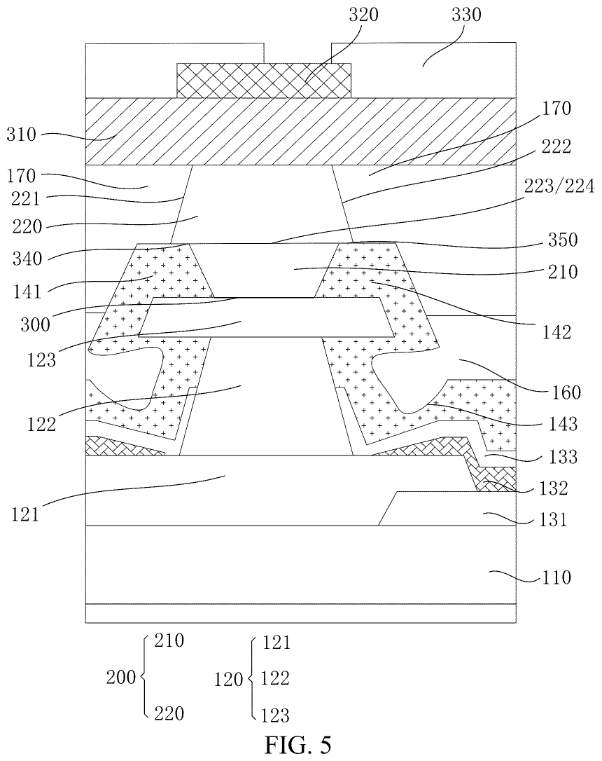

FIG. 4 is a schematic diagram of a film layer structure of a display panel provided in the first embodiment of the present application. As shown in FIG. 4, a leveling region 180 is formed between adjacent partition structures 120. The leveling region 180 is a region with significant height variations. In the leveling region 180, a recess 143 is formed at the location of the partition structure 120. The recess 143 has a polygonal structure and is relatively narrow in space. The height of the horizontal plane on which the upper surface of the first organic encapsulation layer 160 is located is at least flush with the height of the horizontal plane on which the upper surface of the leveling region 180 is located. In this way, during the encapsulation of the first organic encapsulation layer 160, the first organic encapsulation material can quickly flow to the position of the recess 143, ensuring that the leveling region 180 is substantially filled, thereby reducing the difficulty of leveling during the subsequent encapsulation with the second organic encapsulation layer 170.

When printing the first organic encapsulation layer 160, due to its relatively low viscosity, if the first organic encapsulation layer 160 is made too thick, the printed encapsulation adhesive material is likely to overflow from the encapsulation barrier region at the edge of the panel. Therefore, the height of the horizontal plane on which the upper surface of the first organic encapsulation layer 160 is located is set lower than the height of the horizontal plane on which the upper surface of the partition structure 120 is located. Subsequently, the second organic encapsulation layer 170 with relatively higher viscosity is formed, which can be effectively blocked in the encapsulation barrier region at the edge of the panel. The thickness of the first organic encapsulation layer 160 is 1.5 μm to 4 μm. The thickness of the second organic encapsulation layer 170 is 4 μm to 10 μm. That is, the thickness of the second organic encapsulation layer 170 is more than twice that of the first organic encapsulation layer 160, so that while the first organic encapsulation layer 160 ensures the filling and leveling of the leveling region 180, the overall organic encapsulation layer can also be effectively blocked at the edge of the panel. In some embodiments, the thickness of the first organic encapsulation layer 160 is 2.5 μm, which is just sufficient to fill the recesses 143 on both sides. Of course, the thicknesses of the first organic encapsulation layer 160 and the second organic encapsulation layer 170 may also be adjusted according to the requirements of the actual production of the display panel 100, and are not limited herein.

FIG. 5 is a partially enlarged schematic view of portion B in FIG. 4. As shown in FIG. 5, in conjunction with FIG. 4, the display panel 100 (as illustrated in FIG. 1) further includes a third organic encapsulation layer 200. A plurality of second organic encapsulation layers 170 are provided, each disposed between two adjacent partition structures 120. A third encapsulation groove 190 is formed between the adjacent second organic encapsulation layers 170 and the corresponding partition structure 120. The third organic encapsulation layer 200 is disposed within the third encapsulation groove 190. The display panel 100 further includes a second inorganic encapsulation layer 310, a plurality of color filter layers 330, and a plurality of black matrices 320. The second inorganic encapsulation layer 310 is disposed on and covers the third organic encapsulation layer 200 and the second organic encapsulation layer 170. The plurality of color filter layers 330 are disposed on the side of the second inorganic encapsulation layer 310 facing away from the third organic encapsulation layer 200 and the second organic encapsulation layer 170. Each of the black matrices 320 is disposed between two adjacent color filter layers 330, and the orthographic projection of the black matrix 320 on the substrate 110 overlaps or coincides with that of the third organic encapsulation layer 200. The color filter layer 330 is mainly used to filter ambient light.

Each of the light-emitting elements is formed by sequentially stacking an anode 131, a light-emitting layer 132, and a cathode 133. The color of the light-emitting layer 132 may be red, green, or blue, and may further include white. When the light-emitting element 130 of the display panel 100 is red, blue, or green, the color of the color filter in the color filter layer 330 corresponds to the color of the respective light-emitting element 130. The black matrix 320 is mainly used to reduce light mixing and light leakage between adjacent light-emitting elements 130. Since part of the light emitted by the light-emitting element 130 passes through the region beneath the black matrix 320, and is absorbed by the black matrix 320 or the color filter layer 330, the light utilization efficiency of the light-emitting element 130 is reduced.

Therefore, the refractive index of the first organic encapsulation layer 160 and that of the second organic encapsulation layer 170 are set to be the same, and the refractive index of the third organic encapsulation layer 200 is set to be lower than that of each of the first organic encapsulation layer 160 and the second organic encapsulation layer 170, so that the light emitted from the light-emitting element 130 undergoes partial reflection or total reflection at the interface between the second organic encapsulation layer 170 and the third organic encapsulation layer 200, thereby recycling the light emitted by the light-emitting element 130 and preventing the light emitted from the light-emitting element 130 from being absorbed by the color filter layer 330 or the black matrix 320, thus improving light utilization efficiency. The refractive indices of the first organic encapsulation layer 160 and the second organic encapsulation layer 170 are each in the range of 1.6 to 1.8. The refractive index of the third organic encapsulation layer 200 is greater than 1.4 and less than 1.5.

As shown in FIG. 5, the cross-sectional shape of the third organic encapsulation layer 200 in the thickness direction of the substrate 110 is a trapezoidal structure. Specifically, each partition structure 120 includes a pixel defining layer 121, a conductive layer 122, and an insulating layer 123 that are sequentially stacked. The first inorganic encapsulation layer 140 includes a first encapsulation piece 141 and a second encapsulation piece 142 that are spaced apart on the insulating layer 123. A groove structure 300 is formed among the first encapsulation piece 141, the insulating layer 123, and the second encapsulation piece 142. The third organic encapsulation layer 200 includes a first organic encapsulation piece 210 and a second organic encapsulation piece 220 that are sequentially stacked. The first organic encapsulation piece 210 is embedded in the groove structure 300. The lower surface of the first organic encapsulation piece 210 is in contact with a portion of the insulating layer 123. In this way, the first encapsulation piece 141, the first organic encapsulation piece 210, and the second encapsulation piece 142 form an encapsulation with a surrounding structure at the partition structure 120, thereby improving the encapsulation performance above the partition structure 120.

The cross-section of the second organic encapsulation piece 220 in the thickness direction of the substrate 110 is an upright trapezoidal structure. The second organic encapsulation piece 220 includes oppositely arranged first inclined surface 221 and second inclined surface 222. In conjunction with FIG. 4, the arrows in the figure represent part of the emitted light from the light-emitting element 130. In this way, when a portion of the light emitted from the light-emitting element 130 reaches the first inclined surface 221 or the second inclined surface 222, reflection occurs on the first inclined surface 221 or the second inclined surface 222. The reflected light is then emitted from the light-emitting surface corresponding to the light-emitting element 130, thereby converging the portion of the light. Let the angle between the first inclined surface 221 and the horizontal plane, and the angle between the second inclined surface 222 and the horizontal plane each be a, then 60°≤a<90°. In this way, nearly all the light that would otherwise be absorbed above the corresponding partition structure 120 by the color filter layer or by the opposite black matrix 320 can be reflected back, thereby maximizing the convergence of light.

As shown in FIG. 5, the cross-section of the first organic encapsulation piece 210 in the thickness direction of the substrate 110 is an inverted trapezoidal structure. The second organic encapsulation piece 220 further includes a first bottom surface 223. The first organic encapsulation portion includes a first surface 224. The first bottom surface 223 is the longer base of the upright trapezoidal structure of the second organic encapsulation piece 220. The first surface 224 is the longer base of the inverted trapezoidal structure of the first organic encapsulation piece 210. The first bottom surface 223 coincides with or partially overlaps the first surface 224. In the orientation along which the partition structure 120 is arranged, the width of the first bottom surface 223 is greater than that of the first surface 224. That is, the first bottom surface 223 partially abuts against the first encapsulation piece 141 to form a first encapsulation interface 340. The first bottom surface 223 also partially abuts against the second encapsulation piece 142 to form a second encapsulation interface 350. In this way, the third organic encapsulation layer 200 not only forms an embedded encapsulation structure through the fitting of the first organic encapsulation piece 210 with the first encapsulation piece 141 and the second encapsulation piece 142, but also further improves the encapsulation stability of the third organic encapsulation layer 200 through the fitting of the first encapsulation interface 340 with the upper surface of the first encapsulation piece 141 and the second encapsulation interface 350 with the upper surface of the second encapsulation piece 142.

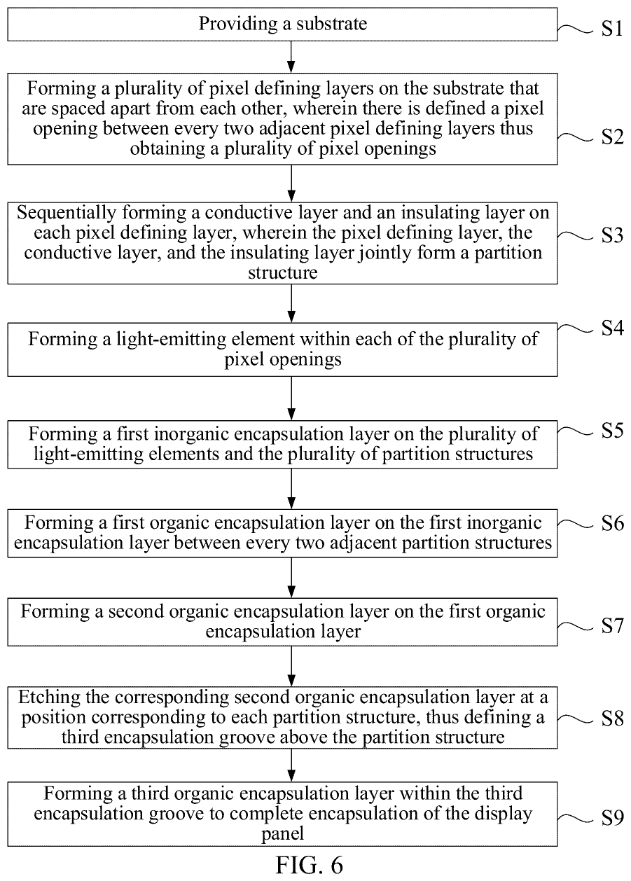

FIG. 6 is a flowchart of a method for manufacturing a display panel according to the present application. As shown in FIG. 6, the present application further discloses a method for manufacturing a display panel, which is used to manufacture the display panel described above and includes the following operations:
S1: providing a substrate;
S2: forming a plurality of pixel defining layers on the substrate that are spaced apart from each other, with a pixel opening formed between every two adjacent pixel defining layers;
S3: forming a conductive layer and an insulating layer sequentially on the pixel defining layer, thus forming a partition structure by the pixel defining layer, conductive layer, and insulating layer;
S4: forming a light-emitting element within each pixel opening;
S5: forming a first inorganic encapsulation layer on the light-emitting element and the partition structure;
S6: forming a first organic encapsulation layer on the first inorganic encapsulation layer between adjacent partition structures;
S7: forming a second organic encapsulation layer on the first organic encapsulation layer;
S8: etching the second organic encapsulation layer at position corresponding to each partition structure, thus forming a third encapsulation groove above the partition structure; and
S9: forming a third organic encapsulation layer within the third encapsulation groove to complete the encapsulation of the display panel.

After forming the second organic encapsulation layer, etching is performed to facilitate the encapsulation and printing of the third organic encapsulation layer, ensuring that the printed shape and structure meet the refractive requirements. Of course, after completing the printing of the first organic encapsulation layer, the third organic encapsulation layer may also be printed first, and the encapsulation and printing of the second organic encapsulation layer may then be performed after the formation of the third organic encapsulation layer is finished. Specifically, the printing speed of the third organic encapsulation layer may be reduced, and an external heat source can be used for auxiliary curing during the printing process, which is also feasible.

### Second Embodiment

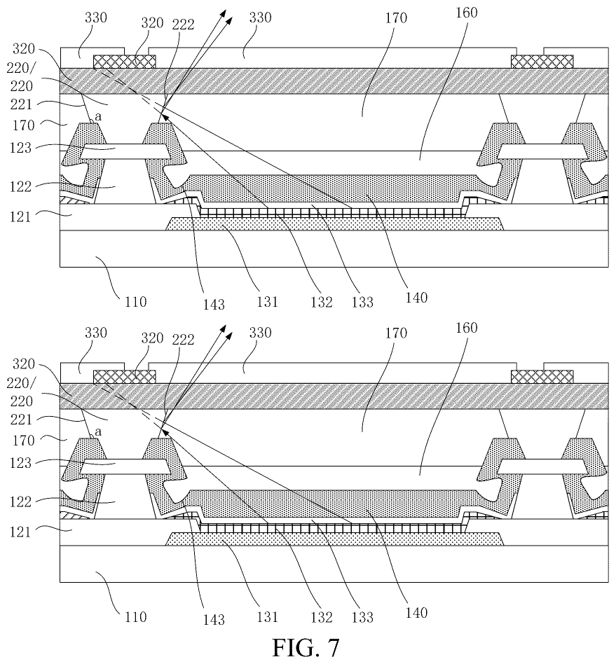

FIG. 7 is a schematic diagram illustrating a film layer structure of a display panel provided in a second embodiment of the present application. As shown in FIG. 7, the second embodiment of the present application differs from the first embodiment in that the cross-sectional structure of the second organic encapsulation piece 220 along the thickness direction of the substrate 110 is an inverted trapezoidal structure. That is, the angle between the first inclined surface 221 and the horizontal or the angle between the second inclined surface 222 and the horizontal plane, denoted as angle a, are each an obtuse angle, where the size of the obtuse angle is: 90°≤a≤120°. When the light emitted at small angles from the light-emitting element 130 reaches the first inclined surface 221 or the second inclined surface 222, it can also be reflected, thereby serving to converge the light.

It should be noted that the limitations of the various steps involved in this solution are not to be interpreted to limit the order of the steps, under the premise of not affecting the implementation of the specific solution. The steps written earlier can be executed first, or later, or even at the same time with the steps written later. As long as this solution can be implemented, it should be regarded as falling in the scope of protection of this application.

It should be noted that the inventive concept of the present application can be formed into many embodiments, but the length of the application document is limited and so these embodiments cannot be enumerated one by one. Therefore, should no conflict be present, the various embodiments or technical features described above can be arbitrarily combined to form new embodiments. After the various embodiments or technical features are combined, the original technical effects may be enhanced.

The foregoing is a further detailed description of the present application with reference to some specific optional implementations, but it cannot be determined that the specific implementation of the present application is limited to these implementations. For those having ordinary skill in the technical field to which the present application pertains, several deductions or substitutions may be made without departing from the concept of the present application, and all these deductions or substitutions should be regarded as falling in the scope of protection of the present application

What is claimed is:

1. A display panel, comprising:
a substrate;
a plurality of partition structures, disposed on the substrate and spaced apart from each other, wherein a pixel opening is formed between every two adjacent partition structures, thus obtaining a plurality of pixel openings;
a plurality of light-emitting elements, disposed within the plurality of pixel openings in one-to-one correspondence;
a first inorganic encapsulation layer, disposed on and covering a side of the plurality of light-emitting elements and the plurality of partition structures facing away from the substrate;
a first organic encapsulation layer, disposed between every two adjacent partition structures; and
a second organic encapsulation layer, disposed on a side of the first organic encapsulation layer facing away from the substrate, wherein the first organic encapsulation layer has a viscosity that is lower than a viscosity of the second organic encapsulation layer.

2. The display panel as recited in claim 1, wherein there is formed a leveling region between every two adjacent partition structures;
wherein a height of a horizontal plane on which an upper surface of the first organic encapsulation layer is located is at least flush with or higher than a height of a horizontal plane on which an upper surface of the leveling region is located;
wherein the height of the horizontal plane on which the upper surface of the first organic encapsulation layer is located is lower than a height of a horizontal plane on which an upper surface of each partition structure is located.

3. The display panel as recited in claim 2, wherein a thickness of the first organic encapsulation layer lies in a range of 1.5 μm to 4 μm, and wherein a thickness of the second organic encapsulation layer lies in a range of 4 μm to 10 μm.

4. The display panel as recited in claim 1, wherein the first organic encapsulation layer and the second organic encapsulation layer are each made of an acrylic-based organic material or an epoxy-based organic material.

5. The display panel as recited in claim 1, further comprising a third organic encapsulation layer; wherein there is comprised a plurality of the second organic encapsulation layers, wherein each of the plurality of second organic encapsulation layers is disposed between two respective adjacent partition structures;
wherein there is defined a third encapsulation groove between every two adjacent second organic encapsulation layers and the corresponding partition structure, and wherein the third organic encapsulation layer is disposed within the third encapsulation groove;
wherein a refractive index of the first organic encapsulation layer is equal to that of the second organic encapsulation layer, and wherein a refractive index of the third organic encapsulation layer is less than that of each of the first organic encapsulation layer and the second organic encapsulation layer.

6. The display panel as recited in claim 5, wherein a refractive index of the first organic encapsulation layer lies in a range of 1.6 to 1.8, and wherein a refractive index of each of the plurality of second organic encapsulation layers lies in the range of 1.6 to 1.8; and
wherein a refractive index of the third organic encapsulation layer is greater than 1.4 and less than 1.5.

7. The display panel as recited in claim 6, wherein a cross section of the third organic encapsulation layer in a thickness direction of the substrate has a trapezoidal structure.

8. The display panel as recited in claim 6, wherein each of the plurality of partition structures comprises a pixel defining layer, a conductive layer, and an insulating layer that are sequentially stacked, wherein the first inorganic encapsulation layer comprises a first encapsulation piece and a second encapsulation piece that are disposed on the insulating layer and that are spaced apart from each other, wherein there is formed a groove structure among the first encapsulation piece, the insulating layer, and the second encapsulation piece,
wherein the third organic encapsulation layer comprises a first organic encapsulation piece and a second organic encapsulation piece that are sequentially stacked, and wherein the first organic encapsulation piece is embedded in the groove structure,
wherein a cross-section of the second organic encapsulation piece in a thickness direction of the substrate is of an upright trapezoidal structure, wherein the second organic encapsulation piece comprises a first inclined surface and a second inclined surface that are disposed opposite to each other, wherein an angle between the first inclined surface and the horizontal plane and an angle between the second inclined surface and the horizontal plane are each denoted as α, and 60≤α<90.

9. The display panel as recited in claim 5, further comprising a second inorganic encapsulation layer, a plurality of color filter layers, and a plurality of black matrices;
wherein the second inorganic encapsulation layer is disposed on the third organic encapsulation layer and the second organic encapsulation layer,
wherein the plurality of color filter layers are disposed on a side of the second inorganic encapsulation layer facing away from the third organic encapsulation layer and the second organic encapsulation layer,
wherein each of the plurality of black matrices is disposed between two adjacent color filter layers, and an orthographic projection of the black matrix on the substrate coincides with or partially overlaps an orthographic projection of the third organic encapsulation layer on the substrate.

10. The display panel as recited in claim 8, wherein a cross-sectional shape of the first organic encapsulation piece in the thickness direction of the substrate is of an inverted trapezoidal structure; wherein the second organic encapsulation piece further comprises a first bottom surface, wherein the first organic encapsulation piece comprises a first surface, wherein the first bottom surface overlaps the first surface; wherein along an orientation in which each partition structure is arranged, a width of the first bottom surface is greater than a width of the first surface;
wherein a portion of the first bottom surface abuts against the first encapsulation piece to form a first encapsulation interface, and wherein another portion of the first bottom surface abuts the second encapsulation piece to form a second encapsulation interface.

11. A method for manufacturing a display panel, comprising:
providing a substrate;
forming a plurality of pixel defining layers on the substrate that are spaced apart from each other, wherein there is defined a pixel opening between every two adjacent pixel defining layers thus obtaining a plurality of pixel openings;
sequentially forming a conductive layer and an insulating layer on each pixel defining layer, wherein the pixel defining layer, the conductive layer, and the insulating layer jointly form a partition structure;
forming a light-emitting element within each of the plurality of pixel openings;
forming a first inorganic encapsulation layer on the plurality of light-emitting elements and the plurality of partition structures;
forming a first organic encapsulation layer on the first inorganic encapsulation layer between every two adjacent partition structures;
forming a second organic encapsulation layer on the first organic encapsulation layer;
etching the corresponding second organic encapsulation layer at a position corresponding to each partition structure, thus defining a third encapsulation groove above the partition structure; and
forming a third organic encapsulation layer within the third encapsulation groove to complete encapsulation of the display panel.

12. A display device, comprising a display panel, the display panel comprising:
a substrate;
a plurality of partition structures, disposed on the substrate and spaced apart from each other, wherein a pixel opening is formed between every two adjacent partition structures, thus obtaining a plurality of pixel openings;
a plurality of light-emitting elements, disposed within the plurality of pixel openings in one-to-one correspondence;
a first inorganic encapsulation layer, disposed on and covering a side of the plurality of light-emitting elements and the plurality of partition structures facing away from the substrate;
a first organic encapsulation layer, disposed between every two adjacent partition structures; and
a second organic encapsulation layer, disposed on a side of the first organic encapsulation layer facing away from the substrate, wherein the first organic encapsulation layer has a viscosity that is lower than a viscosity of the second organic encapsulation layer.

13. The display device as recited in claim 12, wherein there is formed a leveling region between every two adjacent partition structures;
wherein a height of a horizontal plane on which an upper surface of the first organic encapsulation layer is located is at least flush with or higher than a height of a horizontal plane on which an upper surface of the leveling region is located; and
wherein the height of the horizontal plane on which the upper surface of the first organic encapsulation layer is located is lower than a height of a horizontal plane on which an upper surface of each partition structure is located.

14. The display device as recited in claim 13, wherein a thickness of the first organic encapsulation layer lies in a range of 1.5 μm to 4 μm, and wherein a thickness of the second organic encapsulation layer lies in a range of 4 μm to 10 μm.

15. The display device as recited in claim 12, wherein the first organic encapsulation layer and the second organic encapsulation layer are each made of an acrylic-based organic material or an epoxy-based organic material.

16. The display device as recited in claim 12, wherein the display panel further comprises a third organic encapsulation layer; wherein there is comprised a plurality of the second organic encapsulation layers, wherein each of the plurality of second organic encapsulation layers is disposed between two respective adjacent partition structures;
wherein there is defined a third encapsulation groove between every two adjacent second organic encapsulation layers and the corresponding partition structure, and wherein the third organic encapsulation layer is disposed within the third encapsulation groove;
wherein a refractive index of the first organic encapsulation layer is equal to that of the second organic encapsulation layer, and wherein a refractive index of the third organic encapsulation layer is less than that of each of the first organic encapsulation layer and the second organic encapsulation layer.

17. The display device as recited in claim 16, wherein a refractive index of the first organic encapsulation layer lies in a range of 1.6 to 1.8, and wherein a refractive index of each of the plurality of second organic encapsulation layers lies in the range of 1.6 to 1.8; and
wherein a refractive index of the third organic encapsulation layer is greater than 1.4 and less than 1.5.

18. The display device as recited in claim 17, wherein a cross section of the third organic encapsulation layer in a thickness direction of the substrate has a trapezoidal structure.

19. The display device as recited in claim 17, wherein each of the plurality of partition structures comprises a pixel defining layer, a conductive layer, and an insulating layer that are sequentially stacked, wherein the first inorganic encapsulation layer comprises a first encapsulation piece and a second encapsulation piece that are disposed on the insulating layer and that are spaced apart from each other, wherein there is formed a groove structure among the first encapsulation piece, the insulating layer, and the second encapsulation piece,
wherein the third organic encapsulation layer comprises a first organic encapsulation piece and a second organic encapsulation piece that are sequentially stacked, and wherein the first organic encapsulation piece is embedded in the groove structure,
wherein a cross-section of the second organic encapsulation piece in a thickness direction of the substrate is of an upright trapezoidal structure, wherein the second organic encapsulation piece comprises a first inclined surface and a second inclined surface that are disposed opposite to each other, wherein an angle between the first inclined surface and the horizontal plane and an angle between the second inclined surface and the horizontal plane are each denoted as α, and 60°≤α<90°.

20. The display device as recited in claim 16, wherein the display panel further comprises a second inorganic encapsulation layer, a plurality of color filter layers, and a plurality of black matrices;
wherein the second inorganic encapsulation layer is disposed on the third organic encapsulation layer and the second organic encapsulation layer,
wherein the plurality of color filter layers are disposed on a side of the second inorganic encapsulation layer facing away from the third organic encapsulation layer and the second organic encapsulation layer,
wherein each of the plurality of black matrices is disposed between two adjacent color filter layers, and an orthographic projection of the black matrix on the substrate coincides with or partially overlaps an orthographic projection of the third organic encapsulation layer on the substrate.
